(19) United States
(12) Patent Application Publication
(10) Pub. No.: US 2009/0308642 A1
(43) Pub. Date: Dec. 17, 2009

(54) THERMOSETTING RESIN COMPOSITION

(75) Inventors: Katsuto MURATA, Hiki-gun (JP); Koshin NAKAI, Hiki-gun (JP); Makoto HAYASHI, Hiki-gun (JP)

Correspondence Address: OBLON, SPIVAK, MCCLELLAND MAIER & NEUSTADT, L.L.P., 1940 DUKE STREET, ALEXANDRIA, VA, 22314, US

(73) Assignee: TAIYO INK MFG. CO., LTD., Nerima-ku (JP)

(21) Appl. No.: 12/503,210

(22) Filed: Jul. 15, 2009

Related U.S. Application Data
(63) Continuation of application No. PCT/JP2008/050218, filed on Jan. 10, 2008.

(30) Foreign Application Priority Data
Jan. 15, 2007 (JP) 2007-006365

(51) Int. Cl. H05K 1/03; C08L 63/00; C08K 3/36; B32B 27/38

(52) U.S. Cl. 174/255; 523/435; 428/413

(57) ABSTRACT

A thermosetting resin composition contains, as essential components, (A) an epoxy resin having at least two epoxy groups in its molecule, (B) a thermoplastic polyhydroxy polyether resin having a fluorene skeleton, (C) an epoxy curing agent, and (D) a filler. A dry film is obtained by forming a thin film of the thermosetting resin composition on a supporting base film, and a prepreg is obtained by coating and/or impregnating a sheet-like fibrous base material with the thermosetting resin composition. Since they exhibit excellent adhesiveness to a substrate or a conductor and a cured film of the thermosetting resin composition has a relatively low thermal expansion coefficient and a high glass transition point and exhibits high resistance to heat and the capability of being roughened by a roughening treatment, they are useful as a resin insulating layer of a multilayer printed circuit board.

### CROSS-REFERENCE TO RELATED APPLICATIONS

This is a continuation of Application PCT/JP2008/050218, filed Jan. 10, 2008, which was published under PCT Article 21(2).

### BACKGROUND OF THE INVENTION

1. Field of the Invention

This invention relates to a thermosetting resin composition for an interlayer insulating material in a multilayer printed circuit board of the build-up type which is formed by superposing alternately conductor circuit layers and insulating layers, which exhibits excellent adhesiveness to a substrate and to a conductor, has a relatively low thermal expansion coefficient and a high glass transition point, and also exhibits both high resistance to heat and the capability of being roughened by a roughening treatment. The present invention also relates to a dry film and a prepreg obtained by the use thereof, and a multilayer printed circuit board having an interlaminar insulating layer formed by the use thereof.

2. Description of the Prior Art

In recent years, as a process for manufacturing a multilayer printed circuit board, major interest has been shown towards the build-up type manufacturing technique wherein conductor layers and organic insulating layers are alternately built up or superposed on a conductor layer of an internal-layer circuit board. One of the methods for the manufacture of a multilayer printed circuit board heretofore proposed in the art, for example, comprises the steps of applying an epoxy resin composition to an internal-layer circuit board having a circuit formed thereon in advance, thermally curing the applied layer thereby forming resin insulating layer, treating the resin insulating layer with a roughening agent thereby imparting undulating roughened surface thereto, and then forming a conductor layer by plating, as proposed in JP 7-304931A and JP 7-304933A. Another method for the manufacture of a multilayer printed circuit board comprises the steps of laminating an adhesive sheet of an epoxy resin composition onto an internal-layer circuit board having a circuit formed thereon in advance, thermally curing the applied layer thereby forming resin insulating layer, treating the resin insulating layer with a roughening agent thereby imparting undulating roughened surface thereto, and then forming a conductor layer by plating, as proposed in JP 11-87927A.

Now, one example of the process for manufacturing a multilayer printed circuit board by the conventional build-up method will be described below with reference to FIG. 1. First, outer conductor patterns 8 are formed on the opposite surfaces of the laminated circuit board “A” comprising an insulating substrate 1 and prescribed internal-layer conductor patterns 3 and resin insulating layers 4 formed on both sides thereof in advance. Thereafter, resin insulating layers 9 are formed by applying an epoxy resin composition onto the laminated circuit board by a suitable method such as, for example, a screen printing method, spray coating method, or curtain coating method and then thermally curing the applied layers of the composition. When a dry film or a prepreg is used, the resin insulating layers 9 are formed on the laminated circuit board by lamination or hot-plate pressing of the dry film or prepreg to effect thermal curing.

Then, a through-hole 21 is formed in such a manner as to pierce the resin insulating layers 9 and the laminated circuit board “A” or a via hole (not shown) for the electrical interconnection between the connection parts of respective conductor layers is formed. These holes can be formed by a suitable means such as a drill, a metal punch, or a laser beam. Thereafter, a surface roughening treatment of the respective resin insulating layers 9 and a desmear treatment of the respective holes are performed by the use of a roughening agent.

Then, conductor layers are formed on the surfaces of the resin insulating layers 9 by electroless plating, electrolytic plating, or the combination of electroless plating and electrolytic plating. At this time, the conductor layers are formed not only on the surfaces of the resin insulating layers 9 but also on the entire surfaces of the through-hole 21 and the blind hole. Subsequently, prescribed circuit patterns are formed in the conductor layers overlying the surfaces of the resin insulating layers 9 in the usual way to complete the outermost conductor patterns 10 of the outermost layers, as shown in FIG. 1. At this time, a plating layer is also formed on the inner surface of the through-hole 21 as mentioned above. As a result, this plating layer constitutes itself the plated-through hole 20 which electrically interconnect the connection parts 22 of the outermost conductor patterns 10 of the outermost layers and the connection parts 3a of the conductor patterns 3 of the internal layers in the multilayer printed circuit board mentioned above. A multilayer printed circuit board having more layers may be manufactured by further alternately superposing the resin insulating layers and the conductor layers mentioned above. Though the example described thus far represents a case of forming resin insulating layers and conductor layers on a laminated circuit board, a one-sided circuit board or a double-sided circuit board may be used in the place of the laminated circuit board.

As a composition for forming an interlaminar insulating layer in a multilayer printed circuit board, an epoxy resin composition is generally used as described above.

However, since the cured film of a thermosetting composition predominantly containing an epoxy resin is capable of forming a good undulating roughened surface by the roughening treatment only with difficulty and exhibits a relatively low glass transition point, it becomes difficult to cope with the recent demand for high densification of circuits and high performance of electronic devices.

Generally, the process for imparting roughened surface to a cured film of an epoxy resin composition on an internal-layer circuit board and then forming a conductor layer by electroless plating comprises the steps of subjecting the entire surface of the cured composition to swelling with an organic solvents such as N-methyl-2-pyrrolidone, N,N-dimethyl formamide, and methoxy propanol, or an aqueous alkaline solution such as sodium hydroxide and potassium hydroxide, for example, to roughening with an oxidizing agent such as bichromate, permanganate, ozone, hydrogen peroxide/sulfuric acid, and nitric acid, for example, to immersion in an aqueous solution containing a catalyst for plating to effect the adsorption of the catalyst, and to immersion in a plating liquid to deposit plating. Since almost of the chemical agents to be used in this process are in the state of aqueous solution, if the hydrophobic characteristics of the insulating layer becomes unduly high as in the case of the use of conventional epoxy resin composition, the insulating layer has the problem of failing to acquire sufficiently roughened surface and sufficient throwing power of conductor plating, as well as sufficient adhesiveness.

Then, the addition of a hydroxyl group-containing thermoplastic resin to an epoxy resin composition is tried. For example, an epoxy resin composition comprising, as essential components, (A) an epoxy resin having two or more epoxy groups in its molecule, (B) a phenolic curing agent, (C) a phenoxy resin containing a bisphenol S skeleton and having a weight-average molecular weight of 5,000 to 100,000, and (D) a curing accelerator has been proposed in JP 2001-181375A. When such a phenoxy resin is used, however, the glass transition point of the resultant cured film is inadequate. Therefore, the cured film obtained from such an epoxy resin composition containing a phenoxy resin is at a disadvantage in exhibiting inferior resistance to heat, relatively easily suffering a rapid change in physical properties when placed in such environment as high temperature and high humidity, and being liable to cause the reduction in the adhesiveness thereof to a substrate due to the increase in thermal expansion coefficient.

### SUMMARY OF THE INVENTION

Accordingly, an object of the present invention is to provide a thermosetting resin composition for an interlayer insulating material which exhibits excellent adhesiveness to a substrate and to a conductor and is capable of forming a cured film, which film has a relatively low thermal expansion coefficient and a high glass transition point and exhibits both high resistance to heat and the capability of being roughened by a roughening treatment, a dry film and a prepreg obtained by the use thereof.

Another object of the present invention is to provide a multilayer printed circuit board of the build-up type which is formed by alternately superposing conductor circuit layers and insulating layers, wherein a plated conductor layer exhibits high peel strength and an interlaminar insulating layer exhibits excellent characteristics such as resistance to heat and electrical insulating properties.

To accomplish the object mentioned above, the present invention provides a thermosetting resin composition, comprising (A) an epoxy resin having at least two epoxy groups in its molecule, (B) a thermoplastic polyhydroxy polyether resin having a fluorene skeleton, (C) an epoxy curing agent, and (D) a filler.

In a preferred embodiment, the epoxy resin (A) mentioned above is composed of at least two sorts of epoxy resins, and the epoxy resin (A) mentioned above is preferred to include a naphthalene skeleton-containing epoxy resin. Further, it is preferred that the thermoplastic polyhydroxy polyether resin (B) having the fluorene skeleton mentioned above should have a weight-average molecular weight falling in the range of 5,000 to 100,000 and that the filler (D) mentioned above should have an average particle diameter of not more than 3 μm. Particularly, it is desirable that the filler (D) mentioned above be spherical silica.

According to the present invention, there are further provided a dry film comprising a supporting base film and a thin film of the thermosetting resin composition mentioned above formed thereon, and a prepreg comprising a sheet-like fibrous base material coated and/or impregnated with the thermosetting resin composition mentioned above.

Further, the present invention provides a multilayer printed circuit board containing a resin insulating layer and a conductor layer having a prescribed circuit pattern sequentially superposed on an internal-layer circuit board, wherein the resin insulating layer being formed of a cured coating film of the thermosetting resin composition mentioned above, a dry film, or a prepreg, a surface of the resin insulating layer which defines an interface with the conductor layer to be applied thereon being formed in an undulating roughened surface by a roughening treatment, and the conductor layer being joined to said resin insulating layer through the medium of the roughened surface thereof.

Since the thermosetting resin composition of the present invention is an epoxy resin composition which contains the thermoplastic polyhydroxy polyether resin (B) having the fluorene skeleton mentioned above, it exhibits excellent adhesiveness to a substrate and to a conductor and is capable of forming a cured film which has a relatively low thermal expansion coefficient and a high glass transition point and exhibits both high resistance to heat and the capability of being roughened by a roughening treatment. Accordingly, it is optimal as an interlaminar insulating layer of a multilayer printed circuit board.

Therefore, by the use of the thermosetting resin composition of the present invention, its dry film, or a prepreg for the build-up system alternately superposing conductor circuit layers and insulating layers, it is possible to manufacture a multilayer printed circuit board in which the peel strength of a plated conductor layer is high and the interlaminar insulating layer excelling in such properties as resistance to heat and electrically insulating properties is formed.

### BRIEF DESCRIPTION OF THE DRAWINGS

Other objects, features, and advantages of the invention will become apparent from the following description taken together with the drawings, in which:

FIG. 1 is a fragmentary cross-sectional view schematically illustrating one example of the construction of a multilayer printed circuit board manufactured by the conventional build-up method;

FIG. 2 is an electron photomicrograph showing the undulating surface state used for the evaluation criterion in a roughening test, depicting the state of ◯; and

FIG. 3 is an electron photomicrograph showing the undulating surface state used for the evaluation criterion in a roughening test, depicting the state of x.

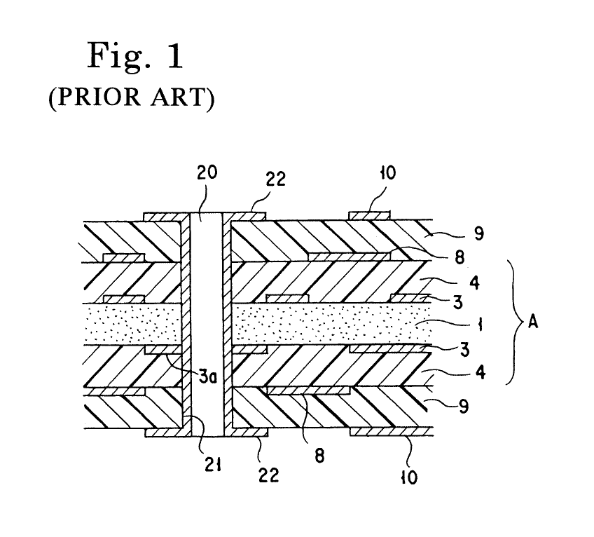

### DETAILED DESCRIPTION OF THE PREFERRED EMBODIMENTS

The present inventors, after pursuing a diligent study to solve the problems mentioned above, have found that when the thermoplastic polyhydroxy polyether resin (B) having the fluorene skeleton mentioned above is added to an epoxy resin composition, the resultant composition is optimal as an interlaminar insulating layer of a multilayer printed circuit board, which has a low thermal expansion coefficient owing to the epoxy resin (A) and a high glass transition point owing to the thermoplastic polyhydroxy polyether resin (B) having the fluorene skeleton with good balance, exhibits excellent adhesiveness to a substrate and to a conductor, and exhibits both high resistance to heat and the capability of being roughened by a roughening treatment. That is to say, since the above-mentioned thermoplastic polyhydroxy polyether resin (B) contains the fluorene skeleton, it exhibits high glass transition point and excellent resistance to heat. Accordingly, the composition containing both components mentioned above is capable of maintaining the high glass transition point owing to the thermoplastic polyhydroxy polyether resin (B) while maintaining a low thermal expansion coefficient owing to the epoxy resin (A) and, as a result, the resultant cured film exhibits a low thermal expansion coefficient and a high glass transition point with good balance. Further, since the thermoplastic polyhydroxy polyether resin (B) mentioned above contains a hydroxyl group, the resultant cured film exhibits good adhesiveness to a substrate and a conductor. Although the resultant cured film will be attacked by a roughening agent only with difficulty, the fillers contained in the cured film surface will be easily fall out the cured film surface because the roughening liquid in the form of solution tends to infiltrate the interfaces between the cured film and fillers, and thus the good roughened surface may be easily formed. Consequently, the roughened surface formed is stable and its anchor effects improve the peel strength of plated conductor layers. As a result, the multilayer printed circuit board having interlaminar insulating layers excelling in resistance to heat, electrical insulating properties, and the like can be produced.

Now, the components of the thermosetting resin composition of the present invention will be described in detail below.

First, as the epoxy resin (A) mentioned above, any polyfunctional epoxy resin having at least two epoxy groups in its molecule may be used. The well-known and widely used epoxy resins such as, for example, a bisphenol A type epoxy resin, a hydrogenated bisphenol A type epoxy resin, a bisphenol F type epoxy resin, a bisphenol S type epoxy resin, a phenol novolak type epoxy resin, an alkylphenol novolak type epoxy resin, a novolak type epoxy resin of bisphenol A, a bixylenol or biphenol type epoxy resin, a naphthalene type epoxy resin, a dicyclopentadiene type epoxy resin, a glycidyl amine type epoxy resin, a trihydroxyphenyl methane type epoxy resin, a tetraphenylol ethane type epoxy resin, a diglycidyl phthalate resin, an epoxidized product of a condensation product of a phenol and an aromatic aldehyde having phenolic hydroxyl group(s), or their bromine atom-containing epoxy resins and phosphorus atom-containing epoxy resins, triglycidyl isocyanurate, and an alicyclic epoxy resin may be used either singly or in the form of a combination of two or more members. It may contain a monofunctional epoxy resin as a reactive diluent.

Although the epoxy resins mentioned above may be used singly, they are preferred to be used in the form of a combination of two or more members. For example, when an epoxy resin which is in the form of liquid at a room temperature and a solid epoxy resin are used together, since the liquid epoxy resin of low molecular weight contributes to the improvement in flexibility and adhesiveness of a cured film obtained and the solid epoxy resin contributes to the increase in a glass transition point, it becomes possible to adjust the balance of the above-mentioned characteristics by adjusting the ratio of these epoxy resins. Particularly, in order to give a low thermal expansion coefficient to the cured film, it is desirable to use a naphthalene skeleton-containing epoxy resin. Although the naphthalene skeleton-containing epoxy resin may be used singly, it is preferred to be used together with other epoxy resin, in an amount of not less than 30% by weight, preferably not less than 50% by weight of the total amount of the epoxy resins. As the naphthalene skeleton-containing epoxy resin, for example, ESN-190 and ESN-360 manufactured by Nippon Steel Chemicals Co., Ltd., HP-4032, EXA-4750, and EXA-4700 manufactured by DIC Inc. (all trade names), etc. may be cited. As another method, it is also desirable that an epoxy resin having an epoxy equivalent of not more than 200 be used together with an epoxy resin having an epoxy equivalent of not less than 200. The epoxy resin having an epoxy equivalent of not less than 200 exhibits little shrinkage after curing and thus is effective in preventing the warpage of a substrate and in imparting flexibility to a cured product. Further, since this epoxy resin is effective in increasing the melt viscosity at the time of lamination by heating and leveling, it is effective in controlling the amount of exudation of resin after molding. On the other hand, the epoxy resin having an epoxy equivalent of not more than 200 exhibits high reactivity and imparts the mechanical strength to a cured product. Further, since its melt viscosity at the time of lamination by heating is low, it contributes to the filling of the resin composition into the gaps between inner layer circuits and the follow to the undulating roughened surface of a copper foil.

Next, as the thermoplastic polyhydroxy polyether resin (B) having the fluorene skeleton mentioned above, for example, the thermoplastic polyhydroxy polyether resin represented by the following general formula (1) may be used suitably.

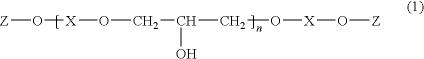

In the above general formula (1), X represents the structure represented by the following general formula (2) or (3), where the ratio of the structure of the general formula (3) to all of X in the general formula (1) is at least 8%, Z represents a hydrogen atom or a glycidyl group, and n is an integer of at least 21.

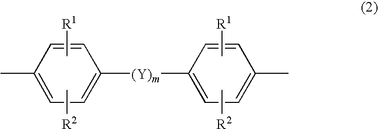

In the above-mentioned general formula (2), R¹ and R² are either one selected from a hydrogen atom, a alkyl group having 1-5 carbon atoms, and a halogen atom, Y is either one of —SO₂—, —CH₂—, —C(CH₃)₂— or —O—, and m is 0 or 1, where R¹ and R² may be the same or different from each other.

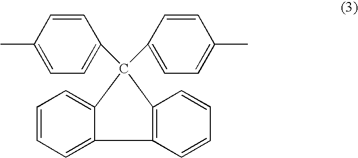

The molecular weight of the above-mentioned thermoplastic polyhydroxy polyether resin (B) having the fluorene skeleton is preferred to be within the limits of 5,000-100,000 (weight-average molecular weight measured by gel permeation chromatography (GPC) based on the standard polystyrene conversion). If the molecular weight is less than 5,000, its thermoplasticity will be lost. Conversely, if the molecular weight exceeds 100,000, the viscosity of the solution obtained by dissolving the resin in a solvent will be too high, which is not desirable because the addition of a large amount of filler will become difficult.

Halogen may be introduced into the above-mentioned thermoplastic polyhydroxy polyether resin (B) having the fluorene skeleton for the purpose of imparting flame retardancy to the resin. When the flame retardancy is imparted by halogen, it will be difficult to impart sufficient flame retardancy to the resin if the halogen content is less than 5% by weight. Conversely, even if the halogen content exceeds 40% by weight, further improvement in the flame retardancy will not be expected. Accordingly, it will be practical to control the halogen content so as to fall in the range of 5% to 40% by weight. Although the halogen element is not limited to a particular one, it is desirable that a bromine compound, a chlorine compound, and a fluoride compound which are commercially available should be used from a viewpoint of commercial production.

As a method for manufacturing the above-mentioned thermoplastic polyhydroxy polyether resin (B) having the fluorene skeleton, a method resorting to the direct reaction of a bivalent phenol with epichlorohydrin, and a method resorting to the addition polymerization of a diglycidyl ether of bivalent phenol and a bivalent phenol are known in the art. Any method may be used to obtain the resin. Incidentally, the methods for manufacturing the above-mentioned thermoplastic polyhydroxy polyether resin are described in JP 11-269264A in detail, the teachings of which are hereby incorporated by reference.

The amount of the above-mentioned thermoplastic polyhydroxy polyether resin (B) having the fluorene skeleton to be incorporated in the thermosetting resin composition of the present invention is preferred to be in the range of 5 to 50 parts by weight, preferably 10 to 40 parts by weight, based on 100 parts by weight of the above-mentioned epoxy resin (A). If the amount of the above-mentioned thermoplastic polyhydroxy polyether resin (B) having the fluorene skeleton is outside the above-mentioned range, the uniformly roughened surface state will be obtained only with difficulty.

As the epoxy curing agent (C) mentioned above, various well-known epoxy resin curing agents or epoxy resin curing accelerator may be used. For example, a phenolic resin, an imidazole compound, an acid anhydride, an aliphatic amine, an alicyclic polyamine, an aromatic polyamine, a tertiary amine, dicyandiamide, guanidine or their epoxy adducts and encapsulized products in the form of microcapsule, organic phosphine compounds such as triphenyl phosphine, tetraphenyl phosphonium, and tetraphenyl borate, and 1,8-diazabicyclo[5.4.0]undecene-7 (product name “DBU”, manufactured by Sun-Apro K.K.) or its derivative may be cited. Any well-known and widely used compounds may be used either singly or in the form of a combination of two or more members irrespective of their classification, a curing agent or a curing accelerator. The amount of the epoxy curing agent (C) mentioned above to be incorporated in the composition is preferred to be in the range of 0.1 to 50 parts by weight, based on 100 parts by weight of the epoxy resin (A). If the amount of the epoxy curing agent to be incorporated is smaller than the lower limit of the range mentioned above, the composition will entail insufficient curing. Conversely, if the epoxy curing agent is added to the composition in an unduly large amount exceeding the upper limit of the range mentioned above, no further effect of promoting the curing will be obtained, rather the composition will tend to pose the problem that the resistance to heat and the mechanical strength thereof will be deteriorated.

Among the other epoxy curing agents mentioned above, a phenolic resin and an imidazole compound are preferred. As the phenolic resin, any well-known and widely used resins such as, for example, a phenol novolak resin, an alkylphenol novolak resin, a bisphenol A novolak resin, a dicyclopentadiene type phenolic resin, a Xylok type phenolic resin, a terpene-modified phenolic resin, and a polyvinyl phenol may be used either singly or in the form of a combination of two or more members.

An imidazole compound may be preferably used from the viewpoint of making the physical properties of a cured product to reveal enough, because it can proceed the reaction slowly in a temperature range (80° C.-130° C.) at the time of drying a solvent in the composition containing the imidazole compound and can proceed the reaction fully in a temperature range (150° C.-200° C.) at the time of curing. Further, the imidazole compound is also preferred from the viewpoint of excelling in adhesiveness to a copper circuit and a copper foil. As concrete examples of the particularly preferred imidazole compound, 2-ethyl-4-methylimidazole, 2-methylimidazole, 2-phenylimidazole, 2-phenyl-4-methylimidazole, bis(2-ethyl-4-methyl-imidazole), 2-phenyl-4-methyl-5-hydroxymethylimidazole, 2-phenyl-4,5-dihydroxymethylimidazole, triazine adduct type imidazole, etc. may be cited. These compounds may be used either singly or in the form of a combination of two or more members.

Next, as the filler (D), any of the heretofore known inorganic fillers and organic fillers may be used and are not limited to particular substances. Since the action of forming the undulating roughened surface on the cured film by a roughening treatment is mainly due to the fact that the roughening liquid infiltrates the interfaces between the cured film and fillers thereby causing falling out of the fillers contained in the cured film surface, an inorganic filler having good compatibility with a roughening liquid is preferred. As the inorganic filler, extender pigment such as, for example, barium sulfate, barium titanate, amorphous silica, crystalline silica, fused silica, spherical silica, talc, clay, magnesium carbonate, calcium carbonate, aluminum oxide, aluminum hydroxide, silicon nitride, and aluminum nitride, and metallic powder of copper, tin, zinc, nickel, silver, palladium, aluminum, iron, cobalt, gold, and platinum, for example, may be cited. These inorganic fillers contribute to the suppression of shrinkage of a coating film at the time of curing and the improvement in such characteristics as adhesiveness and hardness, besides the formation of the undulating roughened surface by the roughening treatment. Among other inorganic fillers mentioned above, silica and barium sulfate which are attacked by a roughening liquid only with difficulty prove to be preferable. Particularly, spherical silica proves to be preferable from the viewpoint that it may be incorporated into the composition in a high proportion. The average particle diameter of the filler is preferred to be not more than 3 μm.

The amount of the filler (D) to be incorporated in the composition is preferred to be in the range of 40 to 150 parts by weight, preferably 50 to 100 parts by weight, based on 100 parts by weight of the total of the epoxy resin (A) and the thermoplastic polyhydroxy polyether resin (B) having the fluorene skeleton mentioned above. If the amount of the filler to be incorporated in the composition is smaller than the lower limit of the range mentioned above, the good undulating roughened surface will be formed only with difficulty. Conversely, if the amount of the filler to be incorporated in the composition is larger than the upper limit of the range mentioned above, the flowability of the composition will be impaired.

The thermosetting resin composition of the present invention may incorporate therein a thermoplastic resin such as, for example, phenoxy resins which are condensation products of epichlorohydrin with various bifunctional phenolic compounds, or phenoxy resins of which hydroxyl group(s) of hydroxyether cite(s) contained in its skeleton is/are esterified with various acid anhydrides or an acid chloride; and polyimide resins, polyamide imide resins, polyphenol resins, polycyanate resins, polyester resins, thermosetting polyphenylene ether resin, etc. in an amount which do not impair the effect of the present invention.

The thermosetting resin composition of the present invention may incorporate therein, as occasion demands, an organic solvent. As the organic solvents, any conventional organic solvents such as, for example, ketones like acetone, methylethyl ketone and cyclohexanone; acetates like ethyl acetate, butyl acetate, cellosolve acetate, propylene glycol monomethylether acetate and carbitol acetate; cellosolves like cellosolve and butyl cellosolve; carbitols like carbitol and butyl carbitol; aromatic hydrocarbons like toluene and xylene; dimethylformamide, and dimethylacetamide may be used either singly or in the form of a combination of two or more members.

The thermosetting resin composition of the present invention may further incorporate therein, as occasion demands, any of known and commonly used coloring agents such as, for example, phthalocyanine blue, phthalocyanine green, iodine green, disazo yellow, crystal violet, titanium oxide, carbon black, and naphthalene black, any of known and commonly used thickening agents such as, for example, asbestos, organobentonite like Orben and Benton (produced by Wilbur Elis K.K.) and finely powdered silica, silicone type, fluorine type, or macromolecular type anti-foaming agents and/or leveling agents, adhesiveness-imparting agents such as thiazole-based compound, triazole-based compound, and silane coupling agents, or any other known and commonly used titanate-based or aluminum-based additives.

Although in the thermosetting resin composition of the present invention the roughened surface may be formed easily owing to the incorporation of the filler (D) into the composition, on the other hand degradation of the surface smoothness etc. tends to generate. In this respect, in accordance with the present invention the degradation of surface smoothness can be prevented and the degradation of the interlaminar insulation due to voids or pinholes can also be prevented by particularly incorporating a anti-foaming agent and/or a leveling agent (E) of the additives mentioned above into the composition.

As concrete examples of the anti-foaming agent and/or leveling agent (E), commercially available anti-foaming agents consisting of a foam breaking polymer solution of the non-silicone type such as, for example, BYK (registered trademark) -054, -055, -057, and -1790 manufactured by BYK Japan K.K., and silicone-based anti-foaming agents such as, for example, BYK (registered trademark) -063, -065, -066N, -067A, -077 manufactured by BYK Japan K.K. and KS-66 (trade name) manufactured by Shin-Etsu Chemical Industries Co., Ltd. may be cited.

The amount of the anti-foaming agent and/or a leveling agent (E) to be incorporated in the composition is preferred to be not more than 5 parts by weight, preferably in the range of 0.01 to 5 parts by weight, based on 100 parts by weight of the total of the epoxy resin (A) and the thermoplastic polyhydroxy polyether resin (B) having the fluorene skeleton mentioned above.

The thermosetting resin composition of the present invention may be provided as a coating material having the viscosity adjusted to a suitable level or as a dry film obtained by applying the thermosetting resin composition onto a supporting base film and drying it to evaporate the solvent contained therein. Further, it may be provided as a prepreg sheet obtained by coating and/or impregnating a sheet-like fibrous base material, such as glass cloth or glass-aramide nonwoven fabric, with the thermosetting resin composition and heating to semi-cure the composition. As the supporting base film, a polyolefin such as polyethylene and polyvinyl chloride, a polyester such as polyethylene terephthalate, a polycarbonate, a polyimide, a release paper, and a metal foil such as copper foil and aluminum foil may be cited. The supporting base film may have been subjected to a mat treatment, a corona treatment, or a releasing agent treatment.

The coating material, the dry film or the prepreg using the thermosetting resin composition mentioned above may be directly applied to an internal-layer circuit board having circuits formed in advance, dried and then cured, or the dry film may be laminated onto an internal-layer circuit board by heating to unify them, and then cured in an oven or cured by hot plate pressing. In the case of the prepreg, it is superposed on an internal-layer circuit board, then they were sandwiched between metal plates through the medium of a release film from both sides, and pressed under pressure and heating.

Among the above-mentioned processes, the lamination method and the hot plate pressing method prove to be preferable because the undulation of the film due to the internal-layer circuit disappears during the melting thereof by heating and cured as it is, thereby eventually giving rise to a multi-layer board having flat surface. Further, when the film or prepreg of the thermosetting resin composition of the present invention is laminated or hot pressed onto a board having an internal-circuit formed in advance, a copper foil or a board having a circuit formed in advance may be simultaneously laminated.

The board obtained in this way is perforated by a drill or a laser such as CO₂ laser and UV-YAG laser. The holes may be through holes aiming at the electrical connection between both sides of the board or conformal via holes aiming at the electrical connection between the circuit of the inner layer and the circuit lying on the surface of the interlaminar insulating layer.

After perforation, for the purpose of forming undulating roughened surfaces in the outermost surfaces, a treatment with a commercially available desmear liquid (roughening agent) or with an oxidizing agent, such as permanganate, bichromate, ozone, hydrogen peroxide/sulfuric acid, nitric acid, or the like, is carried out to remove the residue (smear) present in the inner walls or bottom portions of the holes and also to give birth the anchor effect of a conductor layer (a metal plating layer to be formed in the subsequent step).

After the formation of the holes from which smear has been removed with a desmear liquid and the coating film having the undulating roughened surface, the circuit is formed by a subtractive method, a semi-additive method, or the like. In either method, after a conductor layer is formed by electroless plating or electrolytic plating or both, a thermal treatment called annealing may be performed at about 80° C. to 180° C. for about 10 to 60 minutes for the purpose of removing stress in the metal and for improving the strength.

As the metal plating to be used here, any plating of copper, tin, solder, nickel, etc. may be used and is not limited to a particular one. The plating of a plurality sorts may also be used in combination. The plating to be used here may be replaced by the sputtering of metal or the like.

Now, the present invention will be described more specifically below with reference to working examples, comparative examples, and test examples. It should be noted, however, that the following Examples are intended to be merely illustrative of and in any sense restrictive of the present invention. Wherever the terms “parts” and “%” are used hereinbelow, they invariably refer to those based on weight unless otherwise specified.

### Examples 1-5 and Comparative Examples 1-3

The components of each of the examples shown in Table 1 were compounded at proportions shown correspondingly in the same table and kneaded for dispersion with a three-roll mill to prepare a thermosetting resin composition having the viscosity adjusted to 20 dPa·s±10 dPa·s measured with a rotational viscometer of 5 rpm at 25° C.

### Preparation of an Adhesive Film:

Each of the thermosetting resin compositions obtained as described above was applied to a PET film (Lumirror (registered trademark) 38R75 manufactured by Toray Industries, Inc.; 38 μm) by means of a bar coater so as to form a film of 40 μm thickness after drying and dried at 40-120° C. to prepare an adhesive film.

The adhesive film mentioned above was laminated by heating onto a copper foil of 35 μm thickness by means of a vacuum laminator (MVLP-500 manufactured by MEIKI Co., Ltd.) under the conditions of 5 kgf/cm², 120° C., 1 minute, and 1 Torr, then subjected to leveling with a hot plate pressing machine under the conditions of 10 kgf/cm², 130° C., and 1 minute, and cured in a hot-air circulation type drier under the conditions of 150° C.×60 minutes and further 170° C.×30 minutes. The copper foil of the obtained sample was etched with a commercially available etching liquid to evaluate the physical properties of the cured film. The results are collectively shown in Table 1.

TABLE 1

| Components (parts by weight) | | | Example | | | | | Comp. Example | | |
|---|---|---|---|---|---|---|---|---|---|---|
| and Characteristics | | | 1 | 2 | 3 | 4 | 5 | 1 | 2 | 3 |
| Epoxy resin | | EPPN-501H | 40 | 100 | 40 | 100 | | 40 | 40 | 40 |
| | | HP-4032 | 40 | | 40 | | 100 | 40 | 40 | 40 |
| | | ZX-1059 | 20 | | 20 | | | 20 | 20 | 20 |
| Fluorene skeleton- | | FX-293 | 34 | 34 | 34 | 34 | 34 | | 34 | |
| containing resin | | | | | | | | | | |
| Phenoxy resin | | YP-50 | | | | | | 34 | | |
| Inorganic | Spherical silica | Admafine | 72 | 71 | 67 | | 73 | 72 | | 72 |
| filler | | SO-E2 | | | | | | | | |
| | Calcium carbonate | Micropowder | | | | 73 | | | | |
| | | 3N | | | | | | | | |

| | | | | | | | | | |
|---|---|---|---|---|---|---|---|---|---|
| Phenolic resin | HF-1 | 34 | 32 | 34 | 32 | 32 | 34 | 34 | 34 |
| Epoxy curing agent | 1B2PZ | 1 | 1 | 1 | 1 | 1 | 1 | 1 | 1 |
| Organic solvent | Cyclohexanone | 50 | | | | | | | |
| Anti-foaming agent | BYK-057 | 1 | 1 | 1 | 1 | 1 | 1 | 1 | 1 |

| | | | | | | | | |
|---|---|---|---|---|---|---|---|---|
| Glass transition point Tg (TMA) | 168 | 161 | 167 | 160 | 160 | 105 & | 166 | 170 |
| | | | | | | 174 | | |
| CTE₅₀₋₁₀₀ | 52 | 54 | 53 | 53 | 50 | 58 | 70 | 49 |
| Flame retardancy | V-0 | V-0 | V-0 | V-0 | V-0 | V-1 | V-0 | V-0 |
| Roughened surface | ◯ | ◯ | ◯ | ◯ | ◯ | X | X | X |

Remarks
EPPN-501H: Triphenylglycidyl ether type epoxy resin produced by Nippon Kayaku K.K.
HP-4032: Naphthalene skeleton-containing bifunctional epoxy resin produced by DIC Corporation
ZX-1059: Bisphenol A and bisphenol F mixed type epoxy resin produced by Nippon Kayaku K.K.
FX-293: Fluorene skeleton-containing thermoplastic polyhydroxy polyether resin produced by Tohto Kasei Co., Ltd.
YP-50: Phenoxy resin produced by Tohto Kasei Co., Ltd.
Admafine SO-E2: Spherical silica produced by Admatechs Co., Ltd.
Micropowder 3N: produced by Bihoku Funka Kogyo Co., Ltd.
HF-1: Novolak phenolic resin produced by Meiwa Plastic Industries Ltd.
1B2PZ: Imidazole derivative produced by Shikoku Kasei Kogyo K.K.
BYK-057: produced by BYK Japan K.K.

As being clear from the results shown in Table 1 mentioned above, in each example which used the thermoplastic resin composition of the present invention the cured film had a relatively low thermal expansion coefficient and a high glass transition point and exhibited high resistance to heat and the capability of being roughened by a roughening treatment. On the other hand, in the case of Comparative Examples 1 and 3 using the thermosetting resin composition which does not contain the thermoplastic polyhydroxy polyether resin having the fluorene skeleton and Comparative Example 2 using the thermosetting resin composition which contains the thermoplastic polyhydroxy polyether resin having the fluorene skeleton but not a filler, it was not possible to form good roughened surface.

Incidentally, the physical properties and characteristics shown in Table 1 mentioned above were measured and evaluated as follows.

### Performance Evaluation:

### (1) Glass Transition Temperature, Tg:

The glass transition temperature was measured by TMA (thermomechanical analysis). Incidentally, the unit in Table 1 is [° C.].

### (2) Thermal Expansion Coefficient, CTE:

The thermal expansion coefficient in the range of 50-100° C. was measured by TMA. Incidentally, the unit in Table 1 is [×10⁻⁶/K] or [ppm].

### (3) Test for Flammability:

A test substrate was prepared by laminating the adhesive film mentioned above by heating onto a 1.6 mm FR-4 substrate having both surfaces etched out in advance by means of a vacuum laminator (MVLP-500 manufactured by MEIKI Co., Ltd.) under the conditions of 5 kgf/cm², 120° C., 1 minute, and 1 Torr, then subjected to leveling with a hot plate pressing machine under the conditions of 10 kgf/cm², 130° C., and 1 minute, and cured in a hot-air circulation type drier under the conditions of 150° C.×60 minutes and further 170° C.×30 minutes. The resultant substrate was tested to evaluate the flammability according to the flammability test UL-94.

### (4) Roughening Test:

A test substrate was prepared by forming internal layer circuits from a glass epoxy double-sided copper-clad laminate having copper foil of 18 μm thickness and subjecting both sides of the laminate to a treatment with etchBOND (produced by MEC Co., Ltd.). The adhesive film mentioned above was laminated onto this test substrate by heating by means of a vacuum laminator (MVLP-500 manufactured by MEIKI Co., Ltd.) under the conditions of 5 kgf/cm², 120° C., 1 minute, and 1 Torr, then subjected to leveling with a hot plate pressing machine under the conditions of 10 kgf/cm², 130° C., and 1 minute, and cured in a hot-air circulation type drier under the conditions of 150° C.×60 minutes to prepare a laminate.

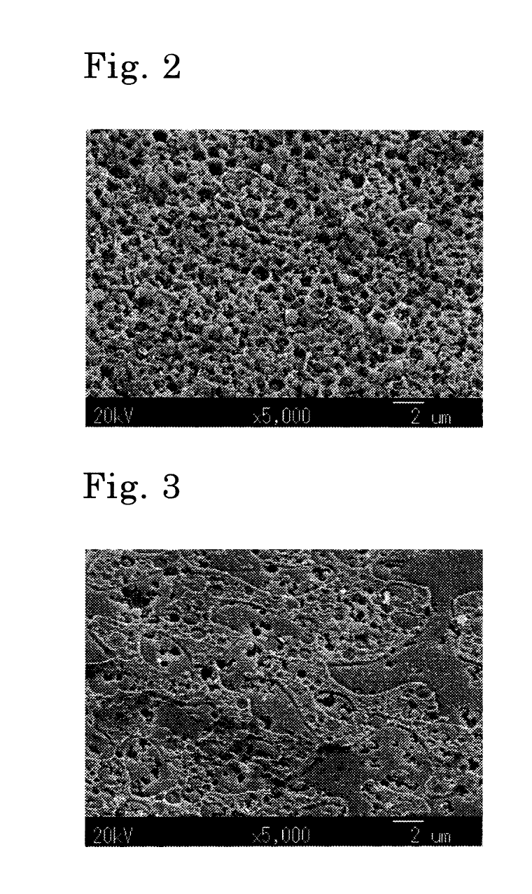

Further, the predetermined through hole parts and the via hole parts of this laminate were perforated with a drill and laser and subsequently subjected to a desmear treatment using a commercially available desmear liquid to form undulating roughened surfaces. The undulating state of surface was observed through an electron microscope to evaluate the roughened state. Incidentally, the evaluation criterion is such that the substrate in which the fine undulating roughened surface on the whole was formed as shown in FIG. 2 was indicated by ◯ and the substrate in which the fine undulating roughened surface on the whole was not formed as shown in FIG. 3 was indicated by x.

Since the thermosetting resin composition of the present invention exhibits excellent adhesiveness to a substrate and to a conductor, has a relatively low thermal expansion coefficient and a high glass transition point, and also exhibits both high resistance to heat and the capability of being roughened by a roughening treatment, it may be advantageously used not only for the formation of an interlayer insulating layer in a multilayer printed circuit board of the build-up type which is formed by superposing alternately conductor circuit layers and insulating layers, but also for the preparation of a dry film and a prepreg for an interlayer insulating material.

While certain specific working examples have been disclosed herein, the invention may be embodied in other specific forms without departing from the spirit or essential characteristics thereof. The described examples are therefore to be considered in all respects as illustrative and not restrictive, the scope of the invention being indicated by the appended claims rather than by the foregoing description and all changes which come within the meaning and range of equivalency of the claims are, therefore, intended to be embraced therein.

The International Application PCT/JP2008/050218, filed Jan. 10, 2008, describes the invention described hereinabove and claimed in the claims appended hereinbelow, the disclosure of which is incorporated here by reference.

What is claimed is:

1. A thermosetting resin composition, comprising:
(A) an epoxy resin having at least two epoxy groups in its molecule;
(B) a thermoplastic polyhydroxy polyether resin having a fluorene skeleton;
(C) an epoxy curing agent; and
(D) a filler.

2. The thermosetting resin composition according to claim 1, further comprising at least either one of an anti-foaming agent and a leveling agent.

3. The thermosetting resin composition according to claim 1, wherein said epoxy resin (A) is composed of at least two sorts of epoxy resins.

4. The thermosetting resin composition according to claim 1, wherein said epoxy resin (A) includes a naphthalene skeleton-containing epoxy resin.

5. The thermosetting resin composition according to claim 1, wherein said thermoplastic polyhydroxy polyether resin (B) having a fluorene skeleton has a weight-average molecular weight falling in the range of 5,000 to 100,000.

6. The thermosetting resin composition according to claim 1, wherein said filler (D) has an average particle diameter of not more than 3 μm.

7. The thermosetting resin composition according to claim 1, wherein said filler (D) is spherical silica.

8. A dry film, comprising a supporting base film and a thin film of said thermosetting resin composition according to claim 1 formed thereon.

9. A prepreg, comprising a sheet-like fibrous base material coated and/or impregnated with said thermosetting resin composition according to claim 1.

10. A multilayer printed circuit board containing a resin insulating layer and a conductor layer having a prescribed circuit pattern sequentially superposed on an internal-layer circuit board, wherein said resin insulating layer being formed of a cured coating film of said thermosetting resin composition according to claim 1, a surface of said resin insulating layer which defines an interface with the conductor layer to be applied thereon being formed in an undulating roughened surface by a roughening treatment, and said conductor layer being joined to said resin insulating layer through the medium of said roughened surface thereof.

11. A multilayer printed circuit board containing a resin insulating layer and a conductor layer having a prescribed circuit pattern sequentially superposed on an internal-layer circuit board, wherein said resin insulating layer being formed of a dry film according to claim 8, a surface of said resin insulating layer which defines an interface with the conductor layer to be applied thereon being formed in an undulating roughened surface by a roughening treatment, and said conductor layer being joined to said resin insulating layer through the medium of said roughened surface thereof.

12. A multilayer printed circuit board containing a resin insulating layer and a conductor layer having a prescribed circuit pattern sequentially superposed on an internal-layer circuit board, wherein said resin insulating layer being formed of a prepreg according to claim 9, a surface of said resin insulating layer which defines an interface with the conductor layer to be applied thereon being formed in an undulating roughened surface by a roughening treatment, and said conductor layer being joined to said resin insulating layer through the medium of said roughened surface thereof.
